(19) United States
(12) Patent Application Publication
(10) Pub. No.: US 2014/0211426 A1
(43) Pub. Date: Jul. 31, 2014

(54) MOTHERBOARD HAVING TWO DISPLAY CONNECTORS

(71) Applicants: HON HAI PRECISION INDUSTRY CO., LTD., New Taipei (TW); HONG FU JIN PRECISION INDUSTRY (ShenZhen) CO., LTD., Shenzhen (CN)

(72) Inventors: ZHENG-YUN CHEN, Shenzhen (CN); JIN-XING CHEN, Shenzhen (CN); AI-YU PAN, Shenzhen (CN)

(73) Assignees: HON HAI PRECISION INDUSTRY CO., LTD., New Taipei (TW); HONG FU JIN PRECISION INDUSTRY (ShenZhen) CO., LTD., Shenzhen (CN)

(21) Appl. No.: 14/144,390

(22) Filed: Dec. 30, 2013

(30) Foreign Application Priority Data
Jan. 25, 2013 (CN) 2013100289657

(51) Int. Cl. H05K 7/02

(52) U.S. Cl. CPC H05K 7/026
USPC 361/748

(57) ABSTRACT

A motherboard includes a resistor, a display card controller, first and second display connectors, and a signal switch chip. A display device is connected to either the first or second display connector. A detecting pin of the first display connector is connected to a power source through the resistor. The signal switch chip is connected between the display card controller and each of the first display connector and the second display connector.

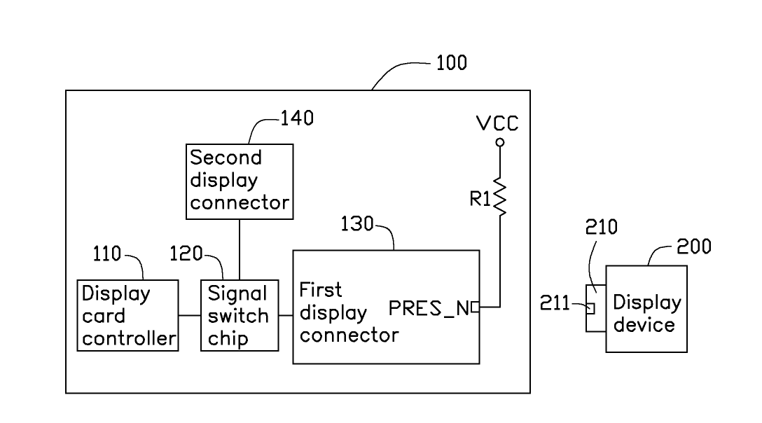

### BACKGROUND

1. Technical Field

The present disclosure relates to motherboards, and particularly to a motherboard comprising two display connectors.

2. Description of Related Art

In general, display connectors arranged on a motherboard are exposed through a rear panel of a chassis of a server for connecting to a display device. However, the space behind the server cabinet may be limited, so it is not easy to connect the display device to the display connector. Therefore, there is room for improvement in the art.

### BRIEF DESCRIPTION OF THE DRAWING

Many aspects of the embodiments can be better understood with reference to the following drawing. The components in the drawing are not necessarily drawn to scale, the emphasis instead being placed upon clearly illustrating the principles of the present embodiments.

The FIGURE is a block diagram of an embodiment of a motherboard.

### DETAILED DESCRIPTION

The disclosure, including the drawing, is illustrated by way of example and not by way of limitation. References to “an” or “one” embodiment in this disclosure are not necessarily to the same embodiment, and such references mean “at least one.”

The FIGURE shows an embodiment of a motherboard 100. The motherboard 100 comprises a display card controller 110, a signal switch chip 120, a first display connector 130, a second display connector 140, and a resistor R1. The first display connector 130 is arranged on a front side of the motherboard 100. The second display connector 140 is arranged on a rear side of the motherboard 100. Thus, when the motherboard 100 is mounted in a chassis of a server, the first display connector 130 is exposed through the front panel of the chassis, and the second display connector 140 is exposed from the rear panel of the chassis. In one embodiment, the first and second display connectors 130 and 140 are video graphics array (VGA) connectors, each of which can connect to an external display connector 210 of a display device 200.

The display card controller 110 is electrically connected to the signal switch chip 120 to output image signals to the signal switch chip 120. The signal switch chip 120 is electrically connected to either the first display connector 130 or the second display connector 140 to output the image signals to the display device 200. A detecting pin PRES N of the first display connector 130 is connected to a power source VCC through the resistor R1.

In use, the power source VCC supplies power to the display device 200 and the first display connector 130 through the first resistor R1. When the external display connector 210 of the display device 200 is connected to the first display connector 130, because a detecting pin 211 of the external display connector 210 is grounded, the detecting pin PRES_N of the first display connector 130 connected to the detecting pin 211 is also grounded, so the detecting pin PRES_N of the first display connector 130 outputs a low-level signal, such as logic 0, to the signal switch chip 120. In response to receiving the low-level signal, the signal switch chip 120 outputs the image signals received from the display card controller 110 to the display device 200 through the first display connector 130.

When the external display connector 210 of the display device 200 is connected to the second display connector 140, because the detecting pin PRES_N of the first display connector 130 is connected to the power source VCC through the resistor R1, the detecting pin PRES_N outputs a high-level signal, such as logic 1, to the signal switch chip 120. In response to receiving the high-level signal, the signal switch chip 120 outputs the image signals received from the display card controller 110 to the second display device 200 through the second display connector 140.

The motherboard 100 obtains the level signals of the detecting pin PRES_N of the first display connector 130 through the signal switch chip 120, and provides the image signals received from the display card controller 110 to the display device 200 through the first display connector 130 or the second display connector 140. The motherboard 100 can connect the display device 200 to either the first display connector 130 or the second display connector 140 according to need, thereby making it more convenient to connect the display device 200 to the motherboard 100.

Even though numerous characteristics and advantages of the disclosure have been set forth in the foregoing description, together with details of the structure and function of the disclosure, the disclosure is illustrative only, and changes may be made in detail, especially in the matters of shape, size, and the arrangement of parts within the principles of the disclosure to the full extent indicated by the broad general meaning of the terms in which the appended claims are expressed.

What is claimed is:

1. A motherboard, comprising:
a resistor;
a display card controller;
a first display connector comprising a first detecting pin connected to a power source through a resistor, wherein when an external display connector of a display device is connected to the first display connector, a grounded second detecting pin of the external display connector is connected to the first detecting pin, to make the first detecting pin grounded;
a second display connector, wherein when the external display connector of the display device is connected to the second display connector, the first detecting pin of the first display connector receives a high level signal from the power source; and
a signal switch chip connected between the display card controller, and each of the first display connector and the second display connector;
wherein when the signal switch chip receives a low level signal from the first detecting pin of the first display connector, the signal switch chip outputs image signals received from the display card controller to the display device through the first display connector; when the signal switch chip receives a high level signal from the first detecting pin of the first display connector, the signal switch chip outputs the image signals received from the display card controller to the display device through the second display connector.

2. The motherboard of claim 1, wherein the first display connector is located at a front side of the motherboard, and the second display connector is located at a rear side of the motherboard.

3. The motherboard of claim 1, wherein the first and second display connectors are video graphics array connectors.
